(19) United States
(12) Patent Application Publication
(10) Pub. No.: US 2020/0278609 A1
(43) Pub. Date: Sep. 3, 2020

(54) PHOTOSENSITIVE CONDUCTIVE PASTE AND FILM FOR FORMING CONDUCTIVE PATTERN

(71) Applicant: Toray Industries, Inc., Tokyo (JP)

(72) Inventors: Tsukuru Mizuguchi, Otsu (JP); Marie Koyama, Otsu (JP)

(21) Appl. No.: 16/647,763

(22) PCT Filed: Oct. 5, 2018
(86) PCT No.: PCT/JP2018/037381

§ 371 Date: Mar. 16, 2020

(30) Foreign Application Priority Data
Oct. 11, 2017 (JP) 2017-197414

(51) Int. Cl. G03F 7/004; G03F 7/033; G03F 7/032; G03F 7/035; H01B 1/22; H05K 1/09

(52) U.S. Cl. CPC G03F 7/0047; G03F 7/033; G03F 7/032; G03F 7/20; H01B 1/22; H05K 1/092; G03F 7/035

(57) ABSTRACT

A photosensitive conductive paste includes a quaternary ammonium salt compound (A), a carboxyl group-containing resin (B), a photopolymerization initiator (C), a reactive monomer having an unsaturated double bond (D) and conductive particles (E). The photosensitive conductive paste exhibits conductivity at low temperature within a short time and is capable of forming fine wiring with excellent adhesion to ITO and bending resistance after being exposed to high-temperature and high-humidity environments by a photolithography method; and a film forms a conductive pattern.

### TECHNICAL FIELD

This disclosure relates to a photosensitive conductive paste, and a film for forming a conductive pattern using the same.

### BACKGROUND

In recent years, there has been proposed a technique in which a fine conductive pattern is formed on a substrate with low heat resistance by a photolithography method using a photosensitive conductive paste. To form a conductive pattern on the substrate with low heat resistance, there is a need to form conductive paths by bringing conductive particles into contact with each other in an organic substance with insulating properties without passing through a firing step of removing the organic substance by heating at high temperature. There have been proposed, as the photosensitive conductive paste used in such technique, for example, a conductive paste including a compound having two or more alkoxy groups, a photosensitive component having an unsaturated double bond, a photopolymerization initiator and a conductive filler (see, for example, JP 2011-180580 A), a photosensitive conductive paste including a conductive powder, an organic binder, a photopolymerizable monomer, a photopolymerization initiator and a solvent (see, for example, WO 2004-061006) and the like.

Meanwhile, there has been proposed a photosensitive conductive paste including dicarboxylic acid and an acid anhydride thereof, a photosensitive component having an unsaturated double bond and an acid value within a range of 40 to 200 mgKOH/g, a photopolymerization initiator and a conductive filler (see, for example, WO 2012-124438) or the like.

However, there was a problem that the conductive patterns obtained by the techniques of JP 2011-180580 A and WO 2004-061006 are hard and have low bending resistance. The conductive pattern obtained by the technique of WO 2012-124438 had a problem that the adhesion decreases when exposed to high-temperature and high-humidity environments in a substrate having low acid resistance such as ITO.

Thus, it could be helpful to provide a photosensitive conductive paste that exhibits conductivity at low temperature within a short time and is capable of forming fine wiring with excellent adhesion to ITO and excellent bending resistance after being exposed to a high-temperature and high-humidity environments by a photolithography method; and a film for forming a conductive pattern.

### SUMMARY

We found that, when the photosensitive conductive paste and the film for forming a conductive pattern include a quaternary ammonium salt compound, the diffusion of metal atoms from the surface of the conductive particles can be promoted to form a fine conductive pattern at lower temperature within a shorter time than conventional ones, and the distortion of the base material can be suppressed to improve the adhesion to ITO and the bending resistance after being exposed to high-temperature and high-humidity environments.

We thus provide:

A photosensitive conductive paste including a quaternary ammonium salt compound (A), a carboxyl group-containing resin (B), a photopolymerization initiator (C), a reactive monomer having an unsaturated double bond (D) and conductive particles (E); and a film for forming a conductive pattern using the same.

It is possible to obtain a photosensitive conductive paste capable of forming fine wiring with excellent adhesion to ITO and bending resistance after being exposed to high-temperature and high-humidity environments; and a film for forming a conductive pattern. By appropriately adjusting the processing method and the constituent members using them, it is possible to form wiring on a curved surface or a sharp angulated surface and to obtain a pressure sensor with high durability.

### BRIEF DESCRIPTION OF THE DRAWINGS

FIG. 1 is a schematic view of an evaluation sample used for the evaluation of specific resistivity of Examples.

FIG. 2 is a schematic cross-sectional view of a pressure sensor produced in Example 38.

FIG. 3 is a schematic cross-sectional view of a pressure sensor produced in Example 39.

FIG. 4 is a schematic view of a cross section, an end surface, and upper and lower surfaces of a circuit board for the measurement of specific resistivity produced in Example 40.

FIG. 5 is a schematic cross-sectional view of a pressure sensor produced in Comparative Example 4.

### DESCRIPTION OF REFERENCE NUMERAL

1: Conductive pattern
2: PET film
A: Short side of sample for measuring specific resistivity
B: Short side opposite to sample for measuring specific resistivity
3: Elastic body
4: Adhesive layer
5: Glass substrate

### DETAILED DESCRIPTION

Our photosensitive conductive paste includes a quaternary ammonium salt compound (A), a carboxyl group-containing resin (B), a photopolymerization initiator (C), a reactive monomer having an unsaturated double bond (D) and conductive particles (E).

The conductive pattern obtained by the photosensitive conductive paste is a composite of an organic component and an inorganic component, and the conductive particles (E) come into contact with each other by an atomic diffusion phenomenon during heat curing, thereby developing the conductivity. Since the quaternary ammonium salt compound (A) promotes the atom diffusion phenomenon during thermal curing, the photosensitive conductive paste contains the quaternary ammonium salt compound (A), thereby making it possible to develop conductivity at low temperature within a short time. Therefore, the photosensitive conductive paste suppresses excessive curing shrinkage during formation of a conductive pattern, thereby making it possible to maintain high adhesion between the conductive pattern and the substrate and bending resistance after being exposed to high-temperature and high-humidity environments. Such effect is the effect peculiar to a quaternary ammonium salt. In general, when a primary or secondary amine compound having high basicity is added, a neutralization reaction between the amine compound and a carboxyl group of the carboxyl group-containing resin (B) occurs, and thus fine patterning properties in photolithography processing are impaired. When a tertiary amine compound is added, the atomic diffusion phenomenon during heat curing does not occur, thus failing to obtain the effect of developing the conductivity at low temperature and within a short time.

When the photosensitive conductive paste includes the carboxyl group-containing resin (B), the alkali developability during photolithography processing is enhanced, thus enabling high-resolution patterning. When the photosensitive conductive paste includes a photopolymerization initiator (C) and a reactive monomer having an unsaturated double bond (D), the photosensitive conductive paste is made insoluble in an alkali by photopolymerization due to exposure during photolithography processing, thus enabling fine patterning.

Examples of the quaternary ammonium salt compound (A) include quaternary ammonium chloride compounds, quaternary ammonium bromide compounds, quaternary ammonium iodide compounds, hydrates thereof and the like. Examples of the quaternary ammonium chloride compound include benzyldimethylstearylammonium chloride, didodecyldimethylammonium chloride, benzylcetyldimethylammonium chloride, benzalkonium chloride, didecyldimethylammonium chloride, benzyldodecyldimethylammonium chloride, hexadecyltrimethylammonium chloride, trimethyltetradecyl ammonium chloride, tetrabutylammonium chloride, dodecyltrimethylammonium chloride, benzoyl chlorine chloride, decyltrimethylammonium chloride, benzyltrimethylammonium chloride, tetrapropylammonium chloride, benzyltrimethylammonium chloride, acetylcholine chloride, tetraethylammonium chloride, diallyldimethyl ammonium chloride, choline chloride, tetramethylammonium chloride and the like. Examples of the quaternary ammonium bromide compound include compounds in which chlorine of the compound exemplified as the quaternary ammonium chloride compound is replaced by bromine, and the like. Examples of the quaternary iodide compound include compounds in which chlorine of the compound exemplified as the quaternary ammonium chloride compound is replaced by iodine and the like. Two or more of these may be included. Of these, the quaternary ammonium chloride compound is preferable because it easily promotes the atom diffusion phenomenon of the conductive particles during heat curing and can further improve the conductivity by short-time heat curing.

The ratio of anions in the quaternary ammonium salt compound (A) (atomic weight of the anion/molecular weight of the quaternary ammonium salt compound) is preferably 10.0% by weight or more. When the ratio of the anion is 10.0% by weight or more, the anion has high stability and the atom diffusion phenomenon of the conductive particles during heat curing is easily promoted, thereby making it possible to further improve the conductivity by short-time heat curing. Meanwhile, the ratio of anions is preferably 50.0% by weight or less. When the ratio of the anion is 50.0% by weight or less, the solubility in the organic component can be improved, thereby making it possible to suppress crystallization of the quaternary ammonium salt compound (A). The ratio of the anion is the weight ratio of the atomic weight of the anion contained in the quaternary ammonium salt compound (A) to the molecular weight of the quaternary ammonium salt compound (A).

At least three of groups bonded to nitrogen atoms of the quaternary ammonium salt compound (A) are preferably CₓH₂ₓ₋₁ (x=1 to 4). When at least three of groups bonded to nitrogen atoms are CₓH₂₋₁ (x=1 to 4), the anion has high stability and the atom diffusion phenomenon of the conductive particles during heat curing is easily promoted, thereby making it possible to improve the conductivity even under the heat curing conditions of low temperature and short time.

The quaternary ammonium salt compound (A) preferably has a molecular weight of 350 or less. When the molecular weight is 350 or less, the anion has high stability and the atom diffusion phenomenon of the conductive particles during heat curing is easily promoted, thereby making it possible to improve the conductivity even under the heat curing conditions of low temperature and short time.

The content of the quaternary ammonium salt compound (A) in the photosensitive conductive paste is preferably 0.01 to 5 parts by weight based on 100 parts by weight of the conductive particles (E). When the content of the quaternary ammonium salt compound (A) is 0.01 part by weight or more, the atom diffusion phenomenon of the conductive particles (E) is easily promoted, thereby making it possible to further improve the conductivity by short-time heat curing. The content of the quaternary ammonium salt compound (A) is more preferably 0.05 part by weight or more, and still more preferably 0.1 part by weight or more. Meanwhile, when the content of the quaternary ammonium salt compound (A) is 5 parts by weight or less, formation of metal halides is suppressed, thereby making it possible to further improve the conductivity.

Examples of the carboxyl group-containing resin (B) include an acrylic copolymer, a carboxylic acid-modified epoxy resin, a carboxylic acid-modified phenol resin, a polyamic acid, a carboxylic acid-modified siloxane polymer and the like. Two or more of these may be included. Of these, an acrylic copolymer or a carboxylic acid-modified epoxy resin each having high ultraviolet transmittance is preferable.

The acrylic copolymer is preferably a copolymer of an acrylic monomer and an unsaturated acid or an acid anhydride thereof.

Examples of the acrylic monomer include phenolic hydroxyl group-containing monomers such as methyl acrylate, ethyl acrylate, 2-ethylhexyl acrylate, n-butyl acrylate, iso-butyl acrylate, iso-propane acrylate, glycidyl acrylate, butoxytriethyleneglycol acrylate, dicyclopentanyl acrylate, dicyclopentenyl acrylate, 2-hydroxyethyl acrylate, isobornyl acrylate, 2-hydroxypropyl acrylate, isodecyl acrylate, isooctyl acrylate, lauryl acrylate, 2-methoxyethyl acrylate, methoxyethylene glycol acrylate, methoxydiethylene glycol acrylate, octafluoropentyl acrylate, phenoxyethyl acrylate, stearyl acrylate, trifluoroethyl acrylate, aminoethyl acrylate, phenyl acrylate, phenoxyethyl acrylate, 1-naphthyl acrylate, 2-naphthyl acrylate, thiophenol acrylate, benzyl mercaptan acrylate, allylated cyclohexyl diacrylate, methoxylated cyclohexyl diacrylate, 1,4-butanediol diacrylate, 1,3-butylene glycol diacrylate, ethylene glycol diacrylate, diethylene glycol diacrylate, triethylene glycol diacrylate, polyethylene glycol diacrylate, neopentyl glycol diacrylate, propylene glycol diacrylate, polypropylene glycol diacrylate, triglycerol diacrylate, trimethylolpropanetriacrylate, ditrimethylolpropane tetraacrylate, dipentaerythritol monohydroxypentaacrylate, dipentaerythritol hexaacrylate, acrylamide, N-methoxymethylacrylamide, N-ethoxymethylacrylamide, N-n-butoxymethylacrylamide, N-isobutoxymethylacrylamide, methacrylphenol, methacryl amidephenol, γ-acryloxypropyltrimethoxysilane, N-(2-hydroxyphenyl)acrylamide, N-(3-hydroxyphenyl)acrylamide, N-(4-hydroxyphenyl)acrylamide, o-hydroxyphenyl acrylate, m-hydroxyphenyl acrylate, p-hydroxyphenyl acrylate, o-hydroxystyrene, m-hydroxystyrene, p-hydroxystyrene, 2-(2-hydroxyphenyl)ethyl acrylate, 2-(3-hydroxyphenyl)ethyl acrylate and 2-(4-hydroxyphenyl)ethyl acrylate, compounds in which an acrylic group thereof is substituted with a methacrylic group, and the like. Of these, a monomer selected from ethyl acrylate, 2-hydroxyethyl acrylate and isobornyl acrylate is particularly preferable. Two or more of these may be used.

Examples of the unsaturated acid or an acid anhydride thereof include acrylic acid, methacrylic acid, itaconic acid, crotonic acid, maleic acid, fumaric acid, vinyl acetate, and acid anhydrides thereof. Two or more of these may be used. The acid value of the acrylic copolymer can be adjusted by the copolymerization ratio of the unsaturated acid.

The carboxylic acid-modified epoxy resin is preferably a reaction product of an epoxy compound and an unsaturated acid or an unsaturated acid anhydride. The carboxylic acid-modified epoxy resin is obtained by modifying an epoxy group of the epoxy compound with a carboxylic acid or a carboxylic anhydride, and has no epoxy group.

Examples of the epoxy compound include glycidyl ethers, glycidyl amines, an epoxy resin and the like. More specifically, examples of glycidyl ethers include methyl glycidyl ether, ethyl glycidyl ether, butyl glycidyl ether, ethylene glycol diglycidyl ether, diethylene glycol diglycidyl ether, propylene glycol diglycidyl ether, tripropylene glycol diglycidyl ether, neopentyl glycol diglycidyl ether, bisphenol A diglycidyl ether, hydrogenated bisphenol A diglycidyl ether, bisphenol F diglycidyl ether, bisphenol S diglycidyl ether, bisphenol fluorene diglycidyl ether, biphenol diglycidyl ether, tetramethyl biphenol glycidyl ether, trimethylolpropane triglycidyl ether, 3′,4′-epoxycyclohexylmethyl-3,4-epoxycyclohexane carboxylate and the like. Examples of glycidyl amines include tert-butyl glycidyl amine and the like. Examples of the epoxy resin include a bisphenol A type epoxy resin, a bisphenol F type epoxy resin, a biphenyl type epoxy resin, a novolak type epoxy resin, a hydrogenated bisphenol A type epoxy resin and the like. Two or more of these may be used.

An unsaturated double bond can be introduced by reacting a compound having an unsaturated double bond such as glycidyl (meth) acrylate with the above-mentioned acrylic copolymer or carboxylic acid-modified epoxy resin. By introducing an unsaturated double bond into the carboxyl group-containing resin (B), the crosslink density of the exposed area during exposure can be improved, thereby making it possible to widen the development margin.

It is possible to preferably use, as the carboxyl group-containing resin (B), those having a urethane bond. When the carboxyl group-containing resin (B) has a urethane bond, the bending resistance of the conductive pattern thus obtained can be further improved. In an acrylic copolymer having a hydroxyl group or a carboxylic acid-modified epoxy resin having a hydroxyl group, examples of the method of introducing a urethane bond into the carboxyl group-containing resin (B) include a method of reacting a diisocyanate compound with these hydroxyl groups. Examples of the diisocyanate compound include hexamethylene diisocyanate, tetramethylxylene diisocyanate, naphthalene-1,5-diisocyanate, tolylene diisocyanate, trimethylhexamethylene diisocyanate, isophorone diisocyanate, allylcyan diisocyanate, norbornane diisocyanate and the like. Two or more of these may be used.

It is also possible to preferably use, as the carboxyl group-containing resin (B), those having a phenolic hydroxyl group. When the carboxyl group-containing resin (B) has a phenolic hydroxyl group, it forms a hydrogen bond with a polar group such as a hydroxyl group or an amino group on the surface of the substrate, thereby making it possible to further improve the adhesion between the conductive pattern thus obtained and the substrate.

The acid value of the carboxyl group-containing resin (B) is preferably 50 to 250 mgKOH/g. When the acid value is 50 mgKOH/g or more, the solubility in a developer increases, thereby making it possible to suppress the generation of development residue. The acid value is more preferably 60 mgKOH/g or more. Meanwhile, when the acid value is 250 mgKOH/g or less, excessive dissolution in the developer can be suppressed, thereby making it possible to suppress film loss of the pattern forming area. The acid value is more preferably 200 mgKOH/g or less. The acid value of the carboxyl group-containing resin (B) can be measured according to JIS K 0070 (1992).

For example, in the acrylic copolymer, the acid value of the carboxyl group-containing resin (B) can be adjusted to a desired range by the ratio of the unsaturated acid in the constituent components. In the carboxylic acid-modified epoxy resin, the acid value can be adjusted to a desired range by reacting a polybasic acid anhydride. In the carboxylic acid-modified phenol resin, the acid value can be adjusted to a desired range by the ratio of the polybasic acid anhydride in the constituent components.

Examples of the photopolymerization initiator (C) include benzophenone derivatives, acetophenone derivatives, thioxanthone derivatives, benzyl derivatives, benzoin derivatives, oxime-based compounds, α-hydroxyketone-based compounds, α-aminoalkylphenone-based compounds, phosphine oxide-based compounds, anthrone compounds, anthraquinone compounds and the like. Examples of the benzophenone derivatives include benzophenone, methyl O-benzoylbenzoate, 4,4′-bis(dimethylamino)benzophenone, 4,4′-bis(diethylamino)benzophenone, 4,4′-dichlorobenzophenone, fluorenone, 4-benzoyl-4′-methyl diphenyl ketone and the like. Examples of the acetophenone derivative include p-t-butyldichloroacetophenone, 4-azide-benzalacetophenone, 2,2′-diethoxyacetophenone and the like. Examples of the thioxanthone derivatives include thioxanthone, 2-methylthioxanthone, 2-chlorothioxanthone, 2-isopropylthioxanthone, diethylthioxanthone and the like. Examples of the benzyl derivative include benzyl, benzyl dimethyl ketal, benzyl-β-methoxyethyl acetal and the like. Examples of the benzoin derivative include benzoin, benzoin methyl ether, benzoin butyl ether and the like. Examples of the oxime-based compound include 1,2-octanedione-1-[4-(phenylthio)-2-(O-benzoyl oxime)], ethanone-1-[9-ethyl-6-(2-methylbenzoyl)-9H-carbazol-3-yl]-1-(O-acetyloxime), 1-phenyl-1,2-butanedione-2-(O-methoxycarbonyl)oxime, 1-phenyl-propanedione-2-(O-ethoxycarbonyl)oxime, 1-phenyl-propanedione-2-(O-benzoyl)oxime, 1,3-diphenyl-propanetrione-2-(O-ethoxycarbonyl)oxime, 1-phenyl-3-ethoxy-propanetrione-2-(O-benzoyl)oxime and the like. Examples of the α-hydroxyketone-based compound include 2-hydroxy-2-methyl-1-phenyl-propan-1-one, 1-[4-(2-hydroxyethoxy)-phenyl]-2-hydroxy-2-methyl-1-propan-1-one and the like. Examples of the α-aminoalkylphenone-based compound include 2-methyl-(4-methylthiophenyl)-2-morpholinopropan-1-one, 2-benzyl-2-dimethylamino-1-(4-morpholinophenyl)-butan-1-one, 2-dimethyl amino-2-(4-methylbenzyl)-1-(4-morpholin-4-yl-phenyl)butan-1-one and the like. Examples of the phosphine oxide-based compound include 2,4,6-trimethylbenzoyl-diphenyl-phosphine oxide, bis(2,4,6-trimethylbenzoyl)-phenylphosphine oxide and the like. Examples of the anthrone compound include anthrone, benzanthrone, dibenzosuberone, methyleneanthrone and the like. Examples of the anthraquinone compound include anthraquinone, 2-t-butyl anthraquinone, 2-amylanthraquinone, 3-chloroanthraquinone and the like. Two or more of these may be included. Of these, an oxime-based compound having high photosensitivity is preferable.

The content of the photopolymerization initiator (C) in the photosensitive conductive paste is preferably 0.05 to 30 parts by weight based on 100 parts by weight of the carboxyl group-containing resin (B). When the content of the photopolymerization initiator (C) is 0.05 part by weight or more, the cured density of the exposed area increases, thereby making it possible to increase the residual film ratio after development. The content of the photopolymerization initiator (C) is more preferably 1 part by weight or more. Meanwhile, when the content of the photopolymerization initiator (C) is 30 parts by weight or less, excessive light absorption due to the photopolymerization initiator (C) in the upper part of the coating film obtained by applying the conductive paste is suppressed. As a result, the conductive pattern can be easily formed into a tapered shape, thereby making it possible to further improve adhesion to the substrate.

Examples of the reactive monomer having an unsaturated double bond (D) include difunctional monomers such as ethylene glycol dimethacrylate, diethylene glycol dimethacrylate, triethylene glycol dimethacrylate, 1,4-butanediol dimethacrylate, neopentyl glycol dimethacrylate, glycerin dimethacrylate, 2-hydroxy-3-acryloyloxypropyl methacrylate, dimethylol-tricyclodecane dimethacrylate, tripropylene glycol diacrylate, dioxane glycol diacrylate, cyclohexane dimethanol dimethacrylate, tricyclodecane dimethanol diacrylate, ethoxylated (4) bisphenol A diacrylate, ethoxylated (10) bisphenol A diacrylate, an acrylic acid adduct of ethylene glycol diglycidyl ether, and an acrylic acid adduct of neopentyl glycol diglycidyl ether; trifunctional monomers such as pentaerythritol triacrylate, pentaerythritol triacrylate, trimethylolpropane triacrylate, trimethylolpropane ethoxy triacrylate and glycerin propoxy triacrylate; tetrafunctional monomers such as dipentaerythritol hexaacrylate, pentaerythritol tetraacrylate, pentaerythritol ethoxy tetraacrylate and ditrimethylolpropane tetraacrylate; and urethane bond-containing monomers such as EBECRYL204, EBECRYL210, EBECRYL220, EBECRYL264, EBECRYL265 and EBECRYL284 manufactured by Daicel Psytech, and CN972, CN975 and CN978 manufactured by Sartomer Company, Inc. Two or more of these may be included. Of these, urethane bond-containing monomers are preferable because the bending resistance of the conductive pattern can be further improved.

The content of the reactive monomer having an unsaturated double bond (D) in the photosensitive conductive paste is preferably 1 to 100 parts by weight based on 100 parts by weight of the carboxyl group-containing resin (B). When the content of the reactive monomer having an unsaturated double bond (D) is 1 part by weight or more, the crosslink density of the exposed area increases, thereby making it possible to increase the solubility difference between the unexposed area and the exposed area in the developer, leading to further improvement in fine patterning properties. Meanwhile, when the content of the reactive monomer having an unsaturated double bond (D) is 100 parts by weight or less, Tg of the conductive pattern thus obtained is suppressed, thereby making it possible to further improve the bending resistance.

Examples of the conductive particles (E) include particles of silver, gold, copper, platinum, lead, tin, nickel, aluminum, tungsten, molybdenum, chromium, titanium, indium, and alloys thereof. Two or more of these may be included. Of these, particles of metal selected from silver, gold and copper are preferable from the viewpoint of the conductivity, and silver particles are more preferable from the viewpoint of cost and stability. The surface of the conductive particles (E) may be coated with a resin, an inorganic oxide or the like.

An aspect ratio, which is the value obtained by dividing the major axis length of the conductive particles (E) by the minor axis length, is preferably 1.0 to 3.0. By setting the aspect ratio of the conductive particles (E) at 1.0 or more, the contact probability between the conductive particles (E) can be increased. The aspect ratio of 1.1 or more is more preferable because the contact probability can be further increased. Meanwhile, by setting the aspect ratio of the conductive particles (E) at 3.0 or less, exposure light is less likely to be blocked, thereby making it possible to widen the development margin when a conductive pattern is formed by a photolithography method. The aspect ratio of the conductive particles (E) is more preferably 2.0 or less. The aspect ratio of the conductive particles (E) can be determined as follows: the conductive particles (E) are observed at a magnification of 15,000 times using a scanning electron microscope (SEM) or a transmission electron microscope (TEM), and the major axis length and the minor axis length of each of the primary particles of 100 conductive particles selected at random are measured, and thus the aspect ratio can be calculated from the average value of both.

The particle diameter of the conductive particles (E) is preferably 0.05 to 5.0 μm. By setting the particle diameter of the conductive particles (E) at 0.05 μm or more, the interaction between the particles is appropriately suppressed, thereby making it possible to improve the dispersibility of the conductive particles (E) in the photosensitive conductive paste. The particle diameter of the conductive particles (E) is more preferably 0.1 μm or more. Meanwhile, by setting the particle size of the conductive particles (E) at 5.0 μm or less, the surface smoothness, pattern accuracy and dimensional accuracy of the conductive pattern thus obtained can be improved. The particle diameter of the conductive particles (E) is more preferably 2.0 μm or less. The particle size of the conductive particles (E) can be measured using a laser irradiation type particle size distribution analyzer. The value of D50 in the particle size distribution obtained by the measurement is defined as the particle diameter (D50) of the conductive particles (E).

The content of the conductive particles (E) in the photosensitive conductive paste is preferably 65 to 90% by weight based on the total solid content. When the content of the conductive particles (E) is 65% by weight or more, the probability of contact between the conductive particles (E) during curing is improved, thereby making it possible to further improve the conductivity and to reduce the probability of disconnection. The content of the conductive particles (E) is more preferably 70% by weight or more. Meanwhile, when the content of the conductive particles (A) is 90% by weight or less, light transmission properties of the coating film in the exposure step is improved, thereby making it possible to further improve fine patterning properties and the bending resistance. The total solid content refers to all constituent components of the photosensitive conductive paste except for the solvent.

The photosensitive conductive paste can include a sensitizer together with the photopolymerization initiator (C). Examples of the sensitizer include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4-bis(diethylamino)benzophenone, 4,4-bis(dimethylamino)chalcone, 4,4-bis(diethylamino)chalcone, p-dimethyl aminocinnamylidene indanone, p-dimethylaminobenzylidene indanone, 2-(p-dimethylaminophenylvinylene)isonaphthothiazole, 1,3-bis(4-dimethylaminophenylvinylene)isonaphthothiazole, 1,3-bis(4-dimethylaminobenzal)acetone,-carbonylbis(4-diethylaminobenzal)acetone, 3,3-carbonylbis(7-diethylaminocoumarin), N-phenyl-N-ethyl ethanolamine, N-phenyl ethanolamine, N-tolyldiethanolamine, isoamyl dimethylaminobenzoate, isoamyl diethylaminobenzoate, 3-phenyl-5-benzoylthiotetrazole, 1-phenyl-5-ethoxycarbonylthiotetrazole and the like. Two or more of these may be included.

The content of the sensitizer in the photosensitive conductive paste is preferably 0.05 to 10 parts by weight based on 100 parts by weight of the carboxyl group-containing resin (B). When the content of the sensitizer is 0.05 parts by weight or more, the photosensitivity is improved. Meanwhile, when the content of the sensitizer is 10 parts by weight or less, excessive light absorption in the upper portion of the coating film obtained by applying the photosensitive conductive paste is suppressed. As a result, the conductive pattern can be easily formed into a tapered shape, thereby making it possible to further improve adhesion to the substrate.

The photosensitive conductive paste can include a solvent. Examples of the solvent include N,N-dimethylacetamide, N,N-dimethylformamide, N-methyl-2-pyrrolidone, dimethylimidazolidinone, dimethyl sulfoxide, y-butyrolactone, ethyl lactate, 1-methoxy-2-propanol, 1-ethoxy-2-propanol, ethylene glycol mono-n-propyl ether, diacetone alcohol, tetrahydrofurfuryl alcohol, propylene glycol monomethyl ether acetate, diethylene glycol monoethyl ether acetate, diethylene glycol monomethyl ether, diethylene glycol monoethyl ether acetate, diethylene glycol monobutyl ether, diethylene glycol, 2,2,4,-trimethyl-1,3-pentanediol monoisobutyrate and the like. Two or more of these may be included. The boiling point of the solvent is preferably 150° C. or higher. When the boiling point is 150° C. or higher, volatilization of the solvent is suppressed, thereby making it possible to suppress thickening of the photosensitive conductive paste.

The photosensitive conductive paste is not preferable because the patterning properties by a photolithography method are impaired if a large amount of a raw material, which causes a curing reaction by a quaternary ammonium salt compound (A) such as an epoxy resin, is present.

The photosensitive conductive paste can include additives such as non-photosensitive polymers having no unsaturated double bond in the molecule, plasticizers, leveling agents, surfactants and silane coupling agents, defoamers and pigments, as long as the desired properties are not impaired.

Examples of the non-photosensitive polymer include polyethylene terephthalate, polyimide precursor, ring-closed polyimide and the like.

Examples of the plasticizers include dibutyl phthalate, dioctyl phthalate, polyethylene glycol, glycerin and the like.

Examples of the leveling agent include a special vinyl-based polymer, a special acrylic polymer and the like.

Examples of the silane coupling agent include methyltrimethoxysilane, dimethyldiethoxysilane, phenyltriethoxysilane, hexamethyl di silazane, 3-methacryloxypropyltrimethoxysilane, 3-glycidoxypropyltrimethoxysilane, vinyltrimethoxysilane and the like.

The photosensitive conductive paste can be produced by mixing a quaternary ammonium salt compound (A), a carboxyl group-containing resin (B), a photopolymerization initiator (C), a reactive monomer having an unsaturated double bond (D), conductive particles (E) and, if necessary, solvents and additives. Examples of the mixing device include a disperser and a kneader such as a three-roller mill, a ball mill and a planetary ball mill.

The film for forming a conductive pattern includes a releasable film and a dried film of the photosensitive conductive paste, and the dried film is laminated on the releasable film.

The releasable film is preferably a film including a release layer on the film surface. Examples of the release agent constituting the release layer include a long-chain alkyl-based release agent, a silicone-based release agent, a fluorine-based release agent and the like. Two or more of these may be used. Of these, a long-chain alkyl-based release agent is preferable because phenomena such as repelling of the developer are less likely to occur in a post-step, particularly a development step, and fine patterning properties are suppressed by suppressing in-plane unevenness, thereby making it possible to further improve fine patterning properties even when the release agent transfer occurs during transferring. The thickness of the release layer is preferably 50 to 500 nm. When the thickness of the release layer is 50 nm or more, transfer unevenness during transfer can be suppressed, and when the thickness is 500 nm or less, transfer of the release agent during transferring can be reduced.

The release force of the release film is preferably 500 to 5,000 mN/20 mm. When the peeling force is 500 mN/20 mm or more, generation of repelling can be suppressed when a dried film of the photosensitive conductive paste is formed. When the peeling force is 5,000 mN/20 mm or less, the process margin during transferring of the dried film to the substrate can be widened. The peeling force of the release film means the peeling force determined as follows: an acrylic adhesive tape “31B” manufactured by Nitto Denko Corporation is put on the release layer surface of the releasable film using a 2 kg roller, and after 30 minutes, the adhesive tape is peeled at a peeling angle of 180° and a peeling speed of 0.3 m/min.

Examples of the film substrate used in the releasable film include films containing polyethylene terephthalate, cycloolefin, polycarbonate, polyimide, aramid, a fluororesin, an acrylic resin or a polyurethane-based resin. From the viewpoint of optical properties, a film containing polyethylene terephthalate, cycloolefin or polycarbonate is preferable. A substrate having high optical properties can be exposed through a releasable film, and the dried film and the photomask do not come into contact with each other, thereby making it possible to suppress mask contamination. The thickness of the film substrate is preferably 5 to 150 μm. When the thickness of the film substrate is 5 μm or more, the film substrate can be stably transported in forming the dried film of the photosensitive conductive paste, and the thickness unevenness of the dried film can be suppressed. The thickness of the film substrate is more preferably 10 μm or more. Meanwhile, when the thickness of the film substrate is 150 μm or less, the influence of diffraction of exposure light during exposure through the releasable film can be reduced, and the fine patterning properties can be further improved. The thickness of the film substrate is more preferably 30 μm or less.

The thickness of the dried film of the photosensitive conductive paste is preferably 0.5 to 10.0 When the thickness of the dried film is 0.5 μm or more, it is possible to suppress variation in resistance value of each wiring and to easily form a pattern on a substrate having irregularities. The thickness of the dried film is more preferably 1.0 μm or more. Meanwhile, when the thickness of the dried film is 10.0 μm or less, light can easily reach the deep portion of the dried film during exposure, thereby making it possible to widen the development margin. The thickness of the dried film is more preferably 5.0 μm or less. The thickness of the dried film of the photosensitive conductive paste can be measured using, for example, a probe-type step profiler such as “SURFCOM” (registered trademark) 1400 (manufactured by TOKYO SEIMITSU CO., LTD.). More specifically, the thickness at three random positions is measured by a probe-type step profiler (length measurement: 1 mm, scanning speed: 0.3 mm/sec) and the average is defined as the thickness.

The film for forming a conductive pattern can be produced by applying the photosensitive conductive paste on a releasable film, followed by drying. Examples of the coating method include spin coating using a spinner, spray coating, roll coating, screen printing, or coating using a blade coater, a die coater, a calendar coater, a meniscus coater or a bar coater. Examples of the drying method include heat drying using an oven, a hot plate or infrared rays, vacuum drying and the like. The drying temperature is preferably 50 to 180° C., and the drying time is preferably 1 minute to several hours.

Next, a description will be made of a method of forming a conductive pattern on a substrate using the photosensitive conductive paste. A dried film of the photosensitive conductive paste is formed on a substrate and the dried film is subjected to exposure and development to form a pattern, and then the obtained pattern is cured, thereby enabling formation of a conductive pattern on the substrate. The dried film of the photosensitive conductive paste may be formed by applying the photosensitive conductive paste on a substrate, followed by drying, or formed by transferring the dried film of the photosensitive conductive paste onto a substrate using the film for forming a conductive pattern.

Examples of the substrate include a polyester film such as a polyethylene terephthalate (PET) film, a polyimide film, an aramid film, an epoxy resin substrate, a polyetherimide resin substrate, a polyether ketone resin substrate, a polysulfone-based resin substrate, a glass substrate, a silicon wafer, an alumina substrate, an aluminum nitride substrate, a silicon carbide substrate, a decorative layer forming substrate, an insulating layer forming substrate and the like.

Examples of the method of applying the photosensitive conductive paste include the methods exemplified as the method of applying the photosensitive conductive paste in the method of producing a film for forming a conductive pattern.

The thickness of the coating film can be appropriately determined according to the method of application, the solid content concentration and the viscosity of the photosensitive conductive paste, and is preferably set so that the thickness of the dried film of the photosensitive conductive paste becomes 0.1 to 50.0 μm. When the thickness of the dried film is 0.1 μm or more, it is possible to suppress variation in resistance value of each wiring. The thickness of the dried film is more preferably 0.5 μm or more, and still more preferably 1.0 μm or more. Meanwhile, when the thickness of the dried film is 50.0 μm or less, light easily reaches the deep portion of the dried film during exposure, thereby making it possible to widen the development margin. The thickness of the dried film is more preferably 10.0 μm or less. The thickness of the dried film of the photosensitive conductive paste can be measured in the same manner as in the thickness of the dried film of the photosensitive conductive paste in the film for forming a conductive pattern.

After forming the coating film, the coating film is preferably dried to volatilize the solvent. Examples of the drying method include the methods exemplified as the method of drying the photosensitive conductive paste in the film for forming a conductive pattern.

Examples of the method of transferring the film for forming a conductive pattern onto the substrate include a method in which the film for forming a conductive pattern is laminated on the substrate such that the dried film of the photosensitive conductive paste is in contact with the substrate, and then the film is transferred by heating and pressing using a nip roller or the like. Hereinafter, this method is called thermal transfer. The film is preferably transferred by heating the nip roller to 50 to 120° C. to improve the transferability.

In forming a conductive pattern by a photolithography method, the dried film of the photosensitive conductive paste is preferably exposed through an arbitrary pattern forming mask. When using a method of providing a dried film by transferring a film for forming a conductive pattern, the film for forming a conductive pattern may be exposed through a releasable film, or may be exposed after peeling the releasable film. As an exposure light source, an i-line (365 nm), an h-line (405 nm) or a g-line (436 nm) of a mercury lamp is preferably used.

After exposure, the unexposed area is dissolved and removed by developing with a developer to obtain a desired pattern. When using a method of providing a dried film by transferring a film for forming a conductive pattern, development is preferably performed after peeling the releasable film. In another example, it is also possible to use a method in which the dried film is exposed and developed on the film for forming a conductive pattern in the same manner as mentioned above, and then the obtained pattern is transferred onto a base material.

Examples of the developer for performing alkali development include aqueous solutions of tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexyl amine, ethylenediamine, hexamethylenediamine and the like. Two or more of these may be used. In some examples, it may be possible to add one or more of polar solvents such as N-methyl-2-pyrrolidone, N,N-dimethylformamide, N,N-dimethylacetamide, dimethyl sulfoxide and y-butyrolactone; alcohols such as methanol, ethanol and isopropanol; esters such as ethyl lactate and propylene glycol monomethyl ether acetate; ketones such as cyclopentanone, cyclohexanone, isobutyl ketone and methyl isobutyl ketone; and surfactants to these aqueous solutions.

Examples of the development method include a method in which a developer is sprayed onto a dried film surface while standing or rotating a substrate including a dried film of an exposed photosensitive conductive paste, a method in which a substrate including a dried film of an exposed photosensitive conductive paste is immersed in a developer, a method in which ultrasonic waves are applied while immersing a substrate including a dried film of an exposed photosensitive conductive paste in a developer and the like.

After the development, a rinsing treatment with a rinsing liquid may be performed. Examples of the rinsing liquid include water or an aqueous solution prepared by adding an alcohol such as ethanol or isopropyl alcohol or an ester such as ethyl lactate or propylene glycol monomethyl ether acetate to water.

By heating and curing the pattern obtained by the development, a conductive pattern can be obtained. The curing temperature is preferably 100 to 200° C. When the curing temperature is 100° C. or higher, the diffusion of atoms is sufficiently induced, thereby making it possible to further improve the conductivity. The curing temperature is more preferably 120° C. or higher. Meanwhile, by setting the curing temperature at 200° C. or lower, the degree of freedom in selection of the base material can be increased. The curing temperature is more preferably 150° C. or lower.

Examples of the curing method include heat drying using an oven, an inert oven or a hot plate, heat drying using electromagnetic waves or microwaves such as an ultraviolet lamp, an infrared heater, a halogen heater and a xenon flash lamp, and vacuum drying. Since the hardness of the conductive pattern increases by heating, chipping or peeling due to contact with other members can be suppressed, and the adhesion between the conductive pattern and the substrate can be further improved.

The conductive pattern obtained by using the photosensitive conductive paste or the film for forming a conductive pattern is suitably used in applications of substrates with wiring, which are used for touch panels, multilayer ceramic capacitors, multilayer inductors, solar cells and the like. Above all, it is more suitably used as peripheral wirings for a touch panel and view area electrodes of a touch panel, which are required to be miniaturized to narrow the frame.

By using the film for forming a conductive pattern, wiring can be easily formed on a curved substrate or a sharp angulated surface such as a substrate end surface. The dried film of the photosensitive conductive paste in the film for forming a conductive pattern is exposed and developed to form a pattern on a releasable film. The film for forming a conductive pattern is laminated on the substrate so that the pattern is in contact with a curved surface on which wiring is to be formed or an end surface of the substrate. By heating and pressing the laminate, the pattern is thermally transferred onto the substrate and then the pattern is heat-cured, thereby enabling the formation of wiring on a curved surface or an end surface of the substrate. After thermally transferring the pattern onto both surfaces and an end surface of the substrate using this method, by heating and curing the pattern, it becomes possible to fabricate a substrate with double-sided wiring in which wiring is formed on both surfaces of the substrate via the substrate end surface. Examples of the method of thermally transferring a pattern formed on a release film include thermocompression bonding using a heat roll or a mold.

It is possible to fabricate a pressure sensor with high durability using the photosensitive conductive paste or the film for forming a conductive pattern.

The pressure sensor performs sensing by arranging electrodes on both sides of an elastic body whose thickness is deformed by pressure, and reading a capacitance change generated between the electrodes. In other words, the greater the rate of change in thickness of the elastic body due to pressure, the higher the sensing properties of the pressure sensor.

Examples of the material of the elastic body used for the pressure sensor include a urethane-based elastomer, a polyamide-based elastomer, an olefin-based elastomer and a polyetherester elastomer. The elastic body preferably has a melting point of 140° C. or higher. The elastic body may be used after being subjected to a foam treatment or a surface embossing treatment. Of these, a surface-embossed product of a polyetherester elastomer is preferable because of its high sensing properties and environmental burden resistance.

The thickness of the elastic body used for the pressure sensor is preferably 10 to 200 μm. When the thickness of the elastic body is 10 μm or more, the amount of displacement of the thickness during application of pressure can be increased, and variation in capacitance value can be suppressed. When the thickness of the elastic body is 200 μm or less, the pressure sensor can be made thinner and lighter.

By a method in which the photosensitive conductive paste is applied to the elastic body surface, followed by drying, exposure, development and curing, or a method in which the film for forming a conductive pattern is transferred onto the elastic body surface, followed by exposure, development and curing, it is possible to directly form an electrode made of a cured product of the photosensitive conductive paste on the surface of the elastic body. Alternatively, an electrode pattern formed on a substrate such as a PET film may be attached to an elastic body using an adhesive. A method of forming an electrode using the photosensitive conductive paste or the film for forming a conductive pattern is preferable from the viewpoint of making the entire pressure sensor thinner. An electrode may be formed on one surface of the elastic body using the photosensitive conductive paste or the film for forming a conductive pattern, and the electrode may be formed on the opposite surface using another method.

### EXAMPLES

Our photosensitive conductive paste will be described below by way of Examples.

The evaluation method in the respective Examples is as follows.

### Fine Patterning Properties (Formation of Fine Wiring)

In Examples 1 to 36 and Comparative Examples 1 to 3, each of the photosensitive conductive pastes obtained in Examples 1 to 36 and Comparative Examples 1 to 3 was applied on a PET film having a thickness of 50 μm “LUMIRROR (registered trademark)” T60 (manufactured by Toray Industries Inc.) so that the thickness after drying became 2 μm, and then dried in a drying oven at 100° C. for 5 minutes.

In Examples 37 and 40 and Comparative Example 6, the photosensitive conductive paste obtained in Example 37 or Comparative Example 1 was applied on the surface of a release layer of a releasable film AL-5 (manufactured by Lintec Corporation, release force: 1,480 mN/20 mm, thickness: 16 μm) so that the thickness after drying became 2 μm, and then dried in a drying oven at 100° C. for 5 minutes to obtain a film for forming a conductive pattern. Subsequently, a PET film and the film for forming a conductive pattern were thermocompression-bonded using a laminator at 60° C. at a speed of 1.0 m/min so that the dried film was brought into contact with the PET film “LUMIRROR (registered trademark)” T60 (manufactured by Toray Industries Inc).

Using an exposure apparatus with an ultra-high pressure mercury lamp (PEM-6M (manufactured by Union Optical Co., Ltd.), exposure was performed over the entire line at an exposure dose of 400 mJ/cm² (based on the radiation having a wavelength of 365 nm) through a photomask adjusted so that the obtained conductive pattern had a constant line-and-space (hereinafter referred to as L/S) in consideration of the line thickening amount of the exposed area in Examples 1 to 36 and Comparative Examples 1 to 3. In Examples 37 and 40 and Comparative Example 6, a photomask was adhered to the surface of the releasable film, and exposure was similarly performed over the entire line at an exposure dose of 50 mJ/cm² (based on the radiation having a wavelength of 365 nm).

After exposure, spray development was performed with an aqueous 0.1% by weight Na₂CO₃ solution for 20 seconds, and a rinsing treatment with ultrapure water was performed. Thereafter, a heat treatment (curing) was performed using a hot air oven at 140° C. for 30 minutes to obtain five types of conductive patterns having different L/S values. The L/S values for each unit are 30/30, 20/20, 15/15, 10/10 and 7/7. The conductive patterns thus obtained were observed by an optical microscope. Among the conductive patterns having no residue between the patterns and having no pattern peeling, the smallest L/S value was defined as the developable L/S value, and the fine patterning property was evaluated.

### Conductivity (Specific Resistivity)

In Examples 1 to 36 and Comparative Examples 1 to 3, each of the photosensitive conductive pastes obtained in Examples 1 to 36 and Comparative Examples 1 to 3 was applied on a PET film having a thickness of 50 μm “LUMIRROR (registered trademark)” T60 so that the thickness after drying became 2 μm, and then dried in a drying oven at 100° C. for 5 minutes.

In Examples 37 and 40 and Comparative Example 6, the photosensitive conductive paste obtained in Example 37 or Comparative Example 1 was applied on the surface of a release layer of a releasable film AL-5 so that the thickness after drying became 2 μm, and then dried in a drying oven at 100° C. for 5 minutes to obtain a film for forming a conductive pattern. Subsequently, a PET film and the film for forming a conductive pattern were thermocompression-bonded using a laminator at 60° C. at a speed of 1.0 m/min so that the dried film was brought into contact with the PET film “LUMIRROR (registered trademark)” T60.

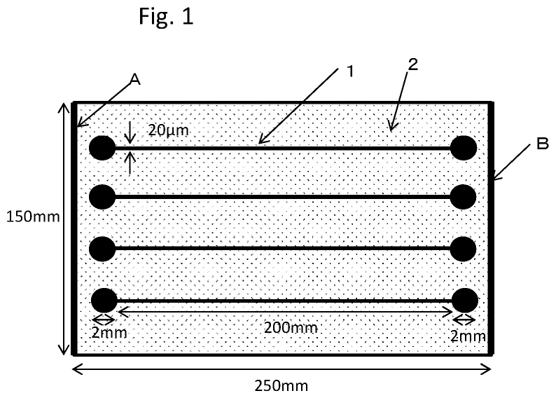

Exposure and development were performed through a photomask under the conditions mentioned above to obtain a wiring pattern. For each of four samples of the wiring pattern thus obtained, three of four samples were heated (cured) in a hot air oven at 140° C. for 15 minutes, 30 minutes, and 60 minutes, respectively, to obtain a sample for the measurement of a specific resistivity with different curing times shown in FIG. 1. The remaining one sample was subjected to a heat treatment in a hot air oven at 120° C. for 30 minutes to obtain a sample for the measurement of a specific resistivity shown in FIG. 1. In FIG. 1, the reference numeral 1 denotes a conductive pattern, and the reference numeral 2 denotes a PET film. The end of each conductive pattern 1 of the thus obtained sample for the measurement of a specific resistivity was connected with an ohmmeter, and the resistance value was measured. The specific resistivity was calculated based on equation (1) and the conductivity was evaluated.

Specific resistance (Ω·cm)={resistance value (Ω)×thickness (m)×line width (m)}/{line length (m)×100} (1).

### Bending Resistance

The sample for the measurement of a specific resistivity shown in FIG. 1 obtained by the method above was mounted on a planar tension-free U-shaped folding tester DLDMLH-FS (Yuasa System Co., Ltd.) so that the conductive pattern is in a state of mountain fold, followed by repetition of the bending operation of bringing the short side A and the short side B shown in FIG. 1 close to one another until the distance between the short side A and the short side B became 10 mm and returning to the original position 10,000 times. The wiring resistance value before and after testing was measured, and the bending resistance was evaluated from the change ratio shown in equation (2).

Change ratio (%)={Wiring resistance value after testing (Ω)/wiring resistance value before testing (Ω)}×100 (2).

Adhesion to ITO after Testing in High-Temperature and High-Humidity Environments

In Examples 1 to 36 and Comparative Examples 1 to 3, each of the photosensitive conductive pastes obtained in Examples 1 to 36 and Comparative Examples 1 to 3 was applied on a PET film with ITO “ELECRYSTA” (registered trademark) V150A-OFSD5C5 (manufactured by Nitto Denko Corporation) so that the thickness after drying became 2 μm, and then dried in a drying oven at 100° C. for 5 minutes.

In Examples 37 and 40 and Comparative Example 6, the photosensitive conductive paste obtained in Example 37 or Comparative Example 1 was applied on the surface of a release layer of a releasable film AL-5 so that the thickness after drying became 2 μm, and then dried in a drying oven at 100° C. for 5 minutes to obtain a film for forming a conductive pattern. Subsequently, a PET film and the film for forming a conductive pattern were thermocompression-bonded at 60° C. at a speed of 1.0 m/min so that the dried film was brought into contact with the PET film with ITO “ELECRYSTA” (registered trademark) V150A-OFSD5C5 (manufactured by Nitto Denko Corporation).

The entire printed surface of each of the obtained laminates was exposed and then cured in a drying oven at 140° C. for 30 minutes. Using a cutter, cuts of 1 mm in width were made on the cured surface in the form of 10×10 grids, and the resulting sample was placed in a thermo-hygrostat chamber SH-661 (manufactured by ESPEC Corp.) at 85° C. and 85% RH for 240 hours. Thereafter, the sample was taken out and a cellophane tape (manufactured by Nichiban Co., Ltd.) was pasted over the grid part and then peeled off, and then the number of remaining grids was visually counted and the adhesion was evaluated.

### Sensing Properties of Pressure Sensor

The pressure sensor thus produced was sandwiched between slide glasses having a thickness of 1 mm and a column having a diameter of 10 mm was pressed into the center of the sample with a force of 500 gf (4.9 N), and then the compression displacement ratio (%) (thickness before pressing−thickness after pressing)/thickness before pressing×100) was measured from the thickness before and after pressing.

### Environmental Burden Resistance of Pressure Sensor

The produced pressure sensor was sandwiched between slide glasses having a thickness of 1 mm and placed in an environmental bath at 85° C. and 85% RH for 240 hours, and then a column having a diameter of 10 mm was pressed into the center of the sample with a force of 500 gf (4.9 N) and the compression displacement ratio (%) (thickness before pressing−thickness after pressing)/thickness before pressing×100) was measured from the thickness before and after pressing.

### Measurement of Capacitance of Pressure Sensor

An AC voltage of 100 kHz and 3 V was applied to the pressure sensor thus produced. If the capacitance value was 10 pF or more, the pressure sensor was rated “good”, whereas, if the capacitance value was less than 10 pF, the pressure sensor was rated “bad”.

Materials used in Examples and Comparative Examples are as follows.

### Quaternary Ammonium Salt Compound (A)

Tetramethylammonium chloride (molecular weight: 109)
Choline chloride (molecular weight: 139)
Triethylmethylammonium chloride (molecular weight: 151)
Diallyldimethylammonium chloride (molecular weight: 161)
Tetraethylammonium chloride (molecular weight: 165)
Acetylcholine chloride (molecular weight: 181)
Benzyltrimethylammonium chloride (molecular weight: 185)
Tetrapropylammonium chloride (molecular weight: 221)
Benzyltriethylammonium chloride (molecular weight: 227)
Decyltrimethylammonium chloride (molecular weight: 235)
Benzoylchlorine chloride (molecular weight: 243)
Dodecyltrimethylammonium chloride (molecular weight: 263)
Tetrabutylammonium chloride (molecular weight: 277)
Trimethyltetradecyl ammonium chloride (molecular weight: 291)
Hexadecyltrimethyl ammonium chloride (molecular weight: 320)
Benzyldodecyldimethylammonium chloride (molecular weight: 339)
Didecyldimethyl ammonium chloride (molecular weight: 362)
Benzalkonium chloride (molecular weight: 368)
Benzylcetyldimethylammonium chloride (molecular weight: 396)
Didodecyldimethylammonium chloride (molecular weight: 418)
Benzyl dimethyl stearyl ammonium chloride (molecular weight: 424)
Tetrabutylammonium bromide (molecular weight: 322)
Tetrabutylammonium iodide (molecular weight: 369)

### Carboxyl Group-Containing Resin (B)

### Synthesis Example 1 Carboxyl Group-Containing Acrylic Copolymer (B-1)

In a reaction vessel in a nitrogen atmosphere, 150 g of diethylene glycol monoethyl ether acetate (hereinafter referred to as “DMEA”) was charged, and the temperature was raised to 80° C. using an oil bath. To this, a mixture of 20 g of ethyl acrylate (hereinafter referred to as “EA”), 20 g of 2-ethylhexyl methacrylate (hereinafter referred to as “2-EHMA”), 20 g of n-butyl acrylate (hereinafter referred to as “BA”), 15 g of N-methylolacrylamide (hereinafter referred to as “MAA”), 25 g of acrylic acid (hereinafter referred to as “AA”), 0.8 g of 2,2′-azobisisobutyronitrile and 10 g of DMEA was added dropwise over 1 hour. After completion of the dropwise addition, a polymerization reaction was performed by heating at 80° C. for 6 hours. Thereafter, 1 g of hydroquinone monomethyl ether was added to terminate the polymerization reaction. The reaction solution thus obtained was purified with methanol to remove unreacted impurities, followed by vacuum drying for 24 hours to obtain a carboxyl group-containing acrylic copolymer (B-1) having a copolymerization ratio (weight basis): EA/2-EHMA/BA/MAA/AA=20/20/20/15/25. The carboxyl group-containing resin (B-1) thus obtained had an acid value of 153 mgKOH/g.

### Synthesis Example 2 Carboxyl Group-Containing Acrylic Copolymer Having an Unsaturated Double Bond (B-2)

In a reaction vessel in a nitrogen atmosphere, 150 g of DMEA was charged, and the temperature was raised to 80° C. using an oil bath. To this, a mixture of 20 g of EA, 40 g of 2-EHMA, 20 g of BA, 15 g of AA, 0.8 g of 2,2′-azobisisobutyronitrile and 10 g of DMEA was added dropwise over 1 hour. After completion of the dropwise addition, a polymerization reaction was performed by heating at 80° C. for 6 hours. Thereafter, 1 g of hydroquinone monomethyl ether was added to terminate the polymerization reaction. Subsequently, a mixture of 5 g of glycidyl methacrylate (hereinafter referred to as “GMA”), 1 g of triethylbenzylammonium chloride and 10 g of DMEA was added dropwise over 0.5 hour. After completion of the dropwise addition, an addition reaction was performed by heating for 2 hours. The reaction solution thus obtained was purified with methanol to remove unreacted impurities, followed by vacuum drying for 24 hours to obtain a carboxyl group-containing acrylic copolymer having an unsaturated double bond (B-2) having a copolymerization ratio (mass basis): EA/2-EHMA/BA/GMA/AA=20/40/20/5/15. The carboxyl group-containing resin (B-2) thus obtained had an acid value of 107 mgKOH/g.

### Synthesis Example 3 Carboxylic Acid-Modified Epoxy Resin (B-3)

In a reaction vessel in a nitrogen atmosphere, 492.1 g of DMEA, 860.0 g of EOCN-103S (manufactured by Nippon Kayaku Co., Ltd; cresol novolak type epoxy resin; epoxy equivalent: 215.0 g/equivalent), 288.3 g of AA, 4.92 g of 2,6-di-tert-butyl-p-cresol and 4.92 g of triphenylphosphine were charged, and the mixture was reacted by heating at a temperature of 98° C. until the acid value of the reaction solution became 0.5 mgKOH/g or less to obtain an epoxy carboxylate compound. Subsequently, 169.8 g of DMEA and 201.6 g of tetrahydrophthalic anhydride were charged in this reaction solution, and the mixture was reacted by heating at 95° C. for 4 hours to obtain a carboxylic acid-modified epoxy resin (B-3). The carboxyl group-containing resin (B-3) thus obtained had an acid value of 104 mgKOH/g.

### Synthesis Example 4 Carboxyl Group-Containing Resin Having a Urethane Bond (B-4)

In a reaction vessel in a nitrogen atmosphere, 368.0 g of RE-3105 (manufactured by Nippon Kayaku Co., Ltd; epoxy equivalent: 184.0 g/equivalent), 141.2 g of AA, 1.02 g of hydroquinone monomethyl ether and 1.53 g of triphenylphosphine were charged, and the mixture was reacted by heating at a temperature of 98° C. until the acid value of the reaction solution became 0.5 mgKOH/g or less to obtain an epoxy carboxylate compound. Thereafter, 755.5 g of DMEA, 268.3 g of 2,2-bis(dimethylol)-propionic acid, 1.08 g of 2-methylhydroquinone and 140.3 g of spiroglycol were added to this reaction solution and the temperature was raised to 45° C. To this solution, 485.2 g of trimethylhexamethylene diisocyanate was gradually added dropwise so that the reaction temperature did not exceed 65° C. After completion of the dropwise addition, the reaction temperature was raised to 80° C. and the reaction was carried out by heating for 6 hours until an absorption at around 2,250 cm⁻¹ disappeared by infrared absorption spectrometry to obtain a carboxyl group-containing resin having a urethane bond (B-4). The carboxyl group-containing resin having a urethane bond (B-4) thus obtained had an acid value of 80.0 mgKOH/g.

### Photopolymerization Initiator (C)

“IRGACURE” (registered trademark) OXE01 (manufactured by BASF Japan Ltd., oxime-based compound) (hereinafter referred to as OXE01).

### Reactive Monomer Having Unsaturated Double Bond (D)

LIGHT ACRYLATE BP-4EA (manufactured by Kyoeisha Chemical Co., Ltd.)

CN972 (urethane bond-containing photopolymerizable compound manufactured by Sartomer).

### Conductive Particles (E)

Ag particles having a particle diameter (D50) of 0.7 μm and an aspect ratio of 1.1

Ag particles having a particle diameter (D50) of 0.7 μm and an aspect ratio of 2.2.

### Elastic Body

HYTREL (registered trademark) 4047N (melting point: 182° C., manufactured by DU PONT-TORAY CO., LTD.)

Single-sided embossed HYTREL (registered trademark) 4047N (diameter: 100 μm, depth: 30 μm) (melting point: 182° C., manufactured by DU PONT-TORAY CO., LTD.)

MIRACTRAN (registered trademark) E394POTA (melting point: 130° C., manufactured by Tosoh Corporation).

### Example 1

In a 100 mL clean bottle, 10.0 g of a carboxyl group-containing acrylic copolymer having an unsaturated double bond (B-2), 0.50 g of OXE01, 5 g of LIGHT ACRYLATE BP-4EA, 10.0 g of DMEA and 0.24 g of tetramethylammonium chloride were charged, followed by mixing using a rotation-revolution vacuum mixer “AWATORI RENTARO” (registered trademark) ARE-310 (manufactured by THINKY Ltd.) to obtain 25.74 g of a resin solution (solid content: 61.1% by mass).

Then, 25.74 g of the resin solution thus obtained and 47.22 g of Ag particles having a particle diameter (D50) of 0.7 μm and an aspect ratio of 1.1 were mixed and kneaded using a three-roller mill (EXAKT M-50; manufactured by EXAKT Advanced Technologies) to obtain 72.96 g of a photosensitive conductive paste. The composition of the photosensitive conductive paste is shown in Table 1.

Using the photosensitive conductive paste thus obtained, fine patterning properties, conductivity, adhesion to ITO after testing high-temperature and high-humidity environments, and bending resistance were respectively evaluated by the methods mentioned above. The value of developable L/S as an evaluation index of fine patterning properties was 10/10, and it was confirmed that satisfactory patterning was performed. The specific resistivity of the conductive pattern was 7.1×10⁻⁵ Ωcm after curing for 60 minutes, 7.5×10⁻⁵ Ωcm after curing for 30 minutes, and 8.1×10⁻⁵ Ωcm after curing for 15 minutes. Regarding the evaluation results of the adhesion to ITO after testing in high-temperature and high-humidity environments, the number of remaining grids was 100. The bending resistance was a change ratio of 120%. The evaluation results are shown in Table 5.

### Examples 2 to 36

Photosensitive conductive pastes each having the composition shown in Tables 1 to 4 were prepared in the same manner as in Example 1, and evaluated in the same manner as in Example 1. The evaluation results are shown in Table 5.

### Example 37

In a 100 mL clean bottle, 10.0 g of carboxyl group-containing resin having a urethane bond (B-4), 0.5 g of OXE-01, 5 g of CN972, 30.0 g of propylene glycol monomethyl ether acetate (hereinafter referred to as PMAC) and 0.24 g of benzyltriethylammonium chloride were charged, followed by mixing using a rotation-revolution vacuum mixer “AWATORI RENTARO” (registered trademark) ARE-310 (manufactured by THINKY Ltd.) to obtain 45.74 g of a resin solution (solid content: 34.4% by mass).

Then, 45.74 g of the resin solution thus obtained and 47.22 g of Ag particles having a particle diameter (D50) of 0.7 μm and an aspect ratio of 1.1 were mixed and kneaded using a three-roller mill (EXAKT M-50; manufactured by EXAKT Advanced Technologies) to obtain 92.96 g of a photosensitive conductive paste A37. The evaluation was performed in the same manner as in Example 1. The evaluation results are shown in Table 5.

### Comparative Example 1

In the same manner as in Example 1, except that the quaternary ammonium salt compound was not added, a photosensitive conductive paste was prepared, and evaluated in the same manner as in Example 1. The evaluation results are shown in Table 5.

### Comparative Examples 2 to 3

In the same manner as in Example 1, except that the compound shown in Table 4 was used in place of the quaternary ammonium salt compound, photosensitive conductive pastes were prepared, and evaluated in the same manner as in Example 1. The evaluation results are shown in Table 5.

### Example 38

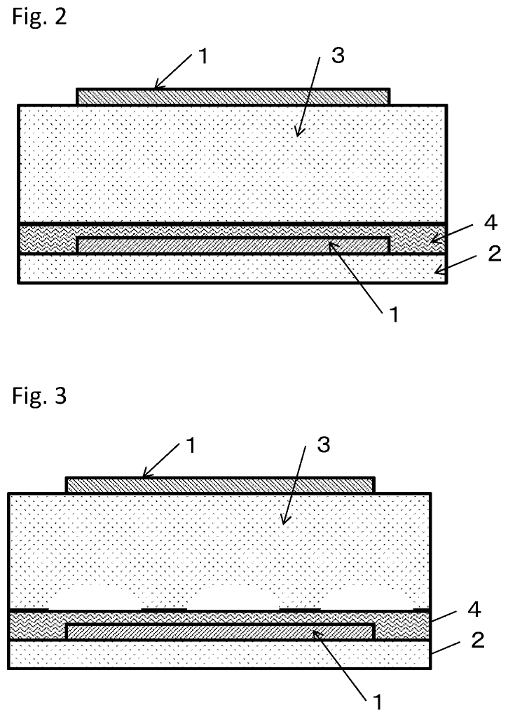

A pressure sensor shown in FIG. 2 was produced. HYTREL (registered trademark) 4047N having a thickness of 100 μm was used as an elastic body 3. Using the photosensitive conductive paste used in Example 1, a circular electrode pattern 1 having a diameter of 30 mm was formed on one surface of the elastic body 3 under the same conditions as in Example 1. Using the photosensitive conductive paste used in Example 1, a circular electrode pattern 1 having a diameter of 30 mm was formed on a PET film 2 having a thickness of 50 μm. As shown in FIG. 2, the PET film 2 with the circular electrode pattern 1 formed thereon was attached to the elastic body 3, on which a single-sided electrode had been formed, with an adhesive layer 4 having a thickness of 10 μm interposed therebetween so that the electrodes are parallel to each other and vertically overlap, thus obtaining a pressure sensor. The sensing properties and the environmental burden resistance of the pressure sensor thus obtained were evaluated. The evaluation results are shown in Table 6.

### Example 39

A pressure sensor shown in FIG. 3 was produced. Single-sided embossed HYTREL (registered trademark) 4047N having a thickness of 100 μm was used as an elastic body 3. Using the photosensitive conductive paste used in Example 1, a circular electrode pattern 1 having a diameter of 30 mm was formed on a flat surface of the elastic body 3 under the same conditions as in Example 1. Using the photosensitive conductive paste used in Example 1, a circular electrode pattern 1 having a diameter of 30 mm was formed on a PET film 2 having a thickness of 50 μm. As shown in FIG. 3, the PET film 2 with the circular electrode pattern 1 formed thereon was attached to an embossed surface of the elastic body 3, on which a single-sided electrode had been formed, with an adhesive layer 4 having a thickness of 10 μm interposed therebetween so that the electrodes are parallel to each other and vertically overlap, thus obtaining a pressure sensor. The sensing properties and the environmental burden resistance of the pressure sensor thus obtained were evaluated. The evaluation results are shown in Table 6.

### Example 40

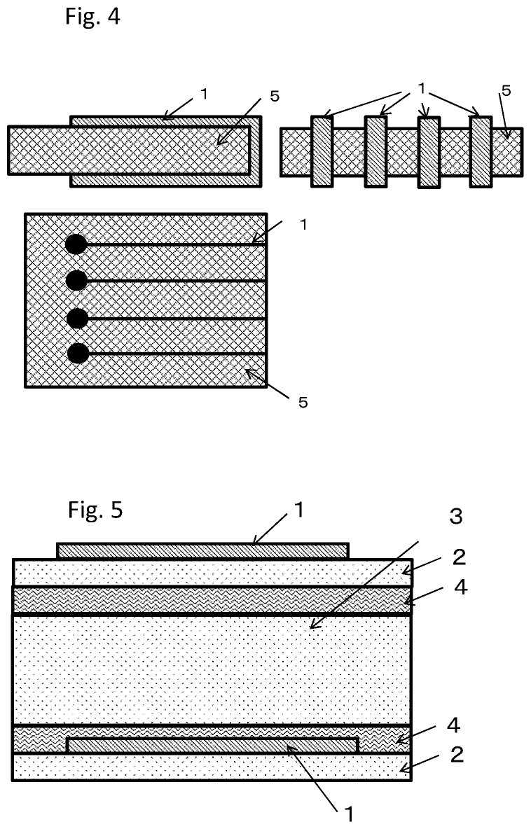

A sample for the measurement of a specific resistivity shown in FIG. 4 was produced. The film for forming a conductive pattern produced in Example 37 was exposed and developed through a photomask under the conditions mentioned above to form a wiring pattern on a releasable film. The wiring pattern was thermally transferred to both sides and the end face of a glass substrate 5 having a thickness of 1 mm at 150° C. using the patterned film for forming a conductive pattern, and then the releasable film was peeled off. Subsequently, the sample was cured in a drying oven at 140° C. for 30 minutes to obtain a sample for the measurement of a specific resistivity shown in FIG. 4. Using the thus obtained sample for the measurement of a specific resistivity, the specific resistance was calculated by the method described above and the conductivity was evaluated. The evaluation results are shown in Table 5.

### Comparative Example 4

A pressure sensor shown in FIG. 5 was produced. HYTREL (registered trademark) 4047N having a thickness of 100 μm was used as the elastic body 3. Using the photosensitive conductive paste used in Comparative Example 1, two PET films 2 each having a thickness of 50 μm with a circular electrode pattern 1 formed thereon were produced. As shown in FIG. 5, two PET films 2 with a circular electrode pattern 1 formed thereon were attached to both sides of an elastic body 3 with an adhesive layer 4 having a thickness of 10 μm interposed therebetween to obtain a pressure sensor.

### Comparative Example 5

In the same manner as in Example 38, except that the photosensitive conductive paste used in Comparative Example 1 was used as the photosensitive conductive paste and MILACTRAN (registered trademark) E394POTA was used as the elastic body 3, a pressure sensor was produced and then evaluated in the same manner as in Example 38. The evaluation results are shown in Table 6.

### Comparative Example 6

Using the photosensitive conductive paste used in Comparative Example 1, the evaluation was performed in the same manner as in Example 40. The evaluation results are shown in Table 5.

TABLE 1

| | Composition | | | | | | | | | | |
|---|---|---|---|---|---|---|---|---|---|---|---|
| | Quaternary ammonium salt compound (A) | | | | | | Reactive | | | | |
| | and other compounds | | | Carboxyl | Photo- | | monomer having | | Conductive particles (E) | | |
| | | | Ratio of | group- | polymerization | | an unsaturated | | Particle | | |
| | | | anions | containing | initiator (C) | | double bond (D) | | diameter | | |
| | | Content | (% by | resin (B) | | Content | | Content | (D50) | Aspect | Content |
| | Type | (*1) | weight) | Type | Type | (*2) | Type | (*2) | (μm) | ratio | (*3) |
| Example 1 | Tetramethylammonium | 0.5 | 21.4 | B-2 | OXE01 | 5 | BP-4EA | 50 | 0.7 | 1.1 | 75 |
| | chloride | | | | | | | | | | |
| Example 2 | Choline chloride | 0.5 | 25.4 | B-2 | OXE01 | 5 | BP-4EA | 50 | 0.7 | 1.1 | 75 |
| Example 3 | Triethylmethylammonium | 0.5 | 23.4 | B-2 | OXE01 | 5 | BP-4EA | 50 | 0.7 | 1.1 | 75 |
| | chloride | | | | | | | | | | |
| Example 4 | Diallyldimethylammonium | 0.5 | 21.9 | B-2 | OXE01 | 5 | BP-4EA | 50 | 0.7 | 1.1 | 75 |
| | chloride | | | | | | | | | | |
| Example 5 | Tetraethylammonium | 0.5 | 21.4 | B-2 | OXE01 | 5 | BP-4EA | 50 | 0.7 | 1.1 | 75 |
| | chloride | | | | | | | | | | |
| Example 6 | Acetylcholine chloride | 0.5 | 19.5 | B-2 | OXE01 | 5 | BP-4EA | 50 | 0.7 | 1.1 | 75 |
| Example 7 | Benzyltrimethylammonium | 0.5 | 15.6 | B-2 | OXE01 | 5 | BP-4EA | 50 | 0.7 | 1.1 | 75 |
| | chloride | | | | | | | | | | |
| Example 8 | Tetrapropylammonium | 0.5 | 16.0 | B-2 | OXE01 | 5 | BP-4EA | 50 | 0.7 | 1.1 | 75 |
| | chloride | | | | | | | | | | |
| Example 9 | Benzyltriethylammonium | 0.5 | 15.6 | B-2 | OXE01 | 5 | BP-4EA | 50 | 0.7 | 1.1 | 75 |
| | chloride | | | | | | | | | | |
| Example 10 | Decyltrimethylammonium | 0.5 | 15.0 | B-2 | OXE01 | 5 | BP-4EA | 50 | 0.7 | 1.1 | 75 |
| | chloride | | | | | | | | | | |
| Example 11 | Benzoylchlorine chloride | 0.5 | 14.5 | B-2 | OXE01 | 5 | BP-4EA | 50 | 0.7 | 1.1 | 75 |
| Example 12 | Dodecyltrimethylammonium | 0.5 | 13.4 | B-2 | OXE01 | 5 | BP-4EA | 50 | 0.7 | 1.1 | 75 |
| | chloride | | | | | | | | | | |

(*1): Parts by weight based on 100 parts by weight of conductive particles (E)
(*2): Parts by weight based on 100 parts by weight of carboxyl group-containing resin (B)
(*3): % by weight in solid content

TABLE 2

| | Composition | | | | | | | | | | |
|---|---|---|---|---|---|---|---|---|---|---|---|
| | Quaternary ammonium salt compound (A) | | | | | | Reactive | | | | |
| | and other compounds | | | Carboxyl | Photo- | | monomer having | | Conductive particles (E) | | |
| | | | Ratio of | group- | polymerization | | an unsaturated | | Particle | | |
| | | | anions | containing | initiator (C) | | double bond (D) | | diameter | | |
| | | Content | (% by | resin (B) | | Content | | Content | (D50) | Aspect | Content |
| | Type | (*1) | weight) | Type | Type | (*2) | Type | (*2) | (μm) | ratio | (*3) |
| Example 13 | Tetrabutylammonium chloride | 0.5 | 12.8 | B-2 | OXE01 | 5 | BP-4EA | 50 | 0.7 | 1.1 | 75 |
| Example 14 | Trimethyltetradecylammonium | 0.5 | 12.1 | B-2 | OXE01 | 5 | BP-4EA | 50 | 0.7 | 1.1 | 75 |
| | chloride | | | | | | | | | | |
| Example 15 | Hexadecyltrimethylammonium | 0.5 | 11.1 | B-2 | OXE01 | 5 | BP-4EA | 50 | 0.7 | 1.1 | 75 |
| | chloride | | | | | | | | | | |
| Example 16 | Benzyldodecyldimethylammonium | 0.5 | 10.4 | B-2 | OXE01 | 5 | BP-4EA | 50 | 0.7 | 1.1 | 75 |
| | chloride | | | | | | | | | | |
| Example 17 | Didecyldimethylammonium | 0.5 | 9.8 | B-2 | OXE01 | 5 | BP-4EA | 50 | 0.7 | 1.1 | 75 |
| | chloride | | | | | | | | | | |
| Example 18 | Benzalkonium chloride | 0.5 | 9.6 | B-2 | OXE01 | 5 | BP-4EA | 50 | 0.7 | 1.1 | 75 |
| Example 19 | Benzylcetyldimethylammonium | 0.5 | 8.9 | B-2 | OXE01 | 5 | BP-4EA | 50 | 0.7 | 1.1 | 75 |
| | chloride | | | | | | | | | | |
| Example 20 | Didodecyldimethylammonium | 0.5 | 8.5 | B-2 | OXE01 | 5 | BP-4EA | 50 | 0.7 | 1.1 | 75 |
| | chloride | | | | | | | | | | |
| Example 21 | Benzyldimethylstearylammonium | 0.5 | 8.4 | B-2 | OXE01 | 5 | BP-4EA | 50 | 0.7 | 1.1 | 75 |
| | chloride | | | | | | | | | | |
| Example 22 | Tetrabutylammonium bromide | 0.5 | 24.8 | B-2 | OXE01 | 5 | BP-4EA | 50 | 0.7 | 1.1 | 75 |
| Example 23 | Tetrabutylammonium iodide | 0.5 | 34.4 | B-2 | OXE01 | 5 | BP-4EA | 50 | 0.7 | 1.1 | 75 |

(*1): Parts by weight based on 100 parts by weight of conductive particles (E)
(*2): Parts by weight based on 100 parts by weight of carboxyl group-containing resin (B)
(*3): % by weight in solid content

TABLE 3

| | Composition | | | | | | | | | | |
|---|---|---|---|---|---|---|---|---|---|---|---|
| | Quaternary ammonium salt compound (A) | | | | | Reactive | | | Conductive particles | | |
| | and other compounds | | | Carboxyl | | monomer having | | | (E) | | |
| | | | Ratio of | group- | Photo- | an unsaturated | | | particle | | |
| | | | anions | containing | polymerization | double bond (D) | | | diameter | | |
| | | Content | (% by | resin (B) | initiator (C) | Content | | Content | (D50) | Aspect | Content |
| | Type | (*1) | weight) | Type | Type | (*2) | Type | (*2) | (μm) | ratio | (*3) |
| Example 24 | Benzyltriethylammonium | 0.02 | 15.6 | B-2 | OXE01 | 5 | BP-4EA | 50 | 0.7 | 1.1 | 75 |
| | chloride | | | | | | | | | | |
| Example 25 | Benzyltriethylammonium | 0.07 | 15.6 | B-2 | OXE01 | 5 | BP-4EA | 50 | 0.7 | 1.1 | 75 |
| | chloride | | | | | | | | | | |
| Example 26 | Benzyltriethylammonium | 1 | 15.6 | B-2 | OXE01 | 5 | BP-4EA | 50 | 0.7 | 1.1 | 75 |
| | chloride | | | | | | | | | | |
| Example 27 | Benzyltriethylammonium | 6 | 15.6 | B-2 | OXE01 | 5 | BP-4EA | 50 | 0.7 | 1.1 | 75 |
| | chloride | | | | | | | | | | |
| Example 28 | Benzyltriethylammonium | 0.5 | 15.6 | B-1 | OXE01 | 5 | BP-4EA | 50 | 0.7 | 1.1 | 75 |
| | chloride | | | | | | | | | | |
| Example 29 | Benzyltriethylammonium | 0.5 | 15.6 | B-3 | OXE01 | 5 | BP-4EA | 50 | 0.7 | 1.1 | 75 |
| | chloride | | | | | | | | | | |
| Example 30 | Benzyltriethylammonium | 0.5 | 15.6 | B-4 | OXE01 | 5 | BP-4EA | 50 | 0.7 | 1.1 | 75 |
| | chloride | | | | | | | | | | |
| Example 31 | Benzyltriethylammonium | 0.5 | 15.6 | B-4 | OXE01 | 5 | CN972 | 50 | 0.7 | 1.1 | 75 |
| | chloride | | | | | | | | | | |
| Example 32 | Benzyltriethylammonium | 0.5 | 15.6 | B-4 | OXE01 | 5 | CN972 | 50 | 0.7 | 1.1 | 63 |
| | chloride | | | | | | | | | | |
| Example 33 | Benzyltriethylammonium | 0.5 | 15.6 | B-4 | OXE01 | 5 | CN972 | 50 | 0.7 | 1.1 | 73 |
| | chloride | | | | | | | | | | |
| Example 34 | Benzyltriethylammonium | 0.5 | 15.6 | B-4 | OXE01 | 5 | CN972 | 50 | 0.7 | 1.1 | 87 |
| | chloride | | | | | | | | | | |
| Example 35 | Benzyltriethylammonium | 0.5 | 15.6 | B-4 | OXE01 | 5 | CN972 | 50 | 0.7 | 1.1 | 92 |
| | chloride | | | | | | | | | | |

(*1): Parts by weight based on 100 parts by weight of conductive particles (E)
(*2): Parts by weight based on 100 parts by weight of carboxyl group-containing resin (B)
(*3): % by weight in solid content

TABLE 4

| | Composition | | | | | | | | | | |
|---|---|---|---|---|---|---|---|---|---|---|---|
| | Quaternary ammonium salt compound (A) | | | | | | Reactive | | | | |
| | and other compounds | | | Carboxyl | Photo- | | monomer having | | Conductive particles (E) | | |
| | | | Ratio of | group- | polymerization | | an unsaturated | | Particle | | |
| | | | anions | containing | initiator (C) | | double bond (D) | | diameter | | |
| | | Content | (% by | resin (B) | | Content | | Content | (D50) | Aspect | Content |
| | Type | (*1) | weight) | Type | Type | (*2) | Type | (*2) | (μm) | ratio | (*3) |
| Example 36 | Benzyltriethylammonium | 0.5 | 15.6 | B-4 | OXE01 | 5 | CN972 | 50 | 0.7 | 2.2 | 75 |
| | chloride | | | | | | | | | | |
| Example 37 | Benzyltriethylammonium | 0.5 | 15.6 | B-4 | OXE01 | 5 | CN972 | 50 | 0.7 | 1.1 | 75 |
| | chloride | | | | | | | | | | |
| Comparative | — | 0.5 | — | B-2 | OXE01 | 5 | BP-4EA | 50 | 0.7 | 1.1 | 75 |
| Example 1 | | | | | | | | | | | |
| Comparative | Maleic acid | 0.5 | — | B-2 | OXE01 | 5 | BP-4EA | 50 | 0.7 | 1.1 | 75 |
| Example 2 | | | | | | | | | | | |
| Comparative | Phenothiazine | 0.5 | — | B-2 | OXE01 | 5 | BP-4EA | 50 | 0.7 | 1.1 | 75 |
| Example 3 | | | | | | | | | | | |

(*1): Parts by weight based on 100 parts by weight of conductive particles (E)
(*2): Parts by weight based on 100 parts by weight of carboxyl group-containing resin (B)
(*3): % by weight in solid content

TABLE 5

| | Fine | Conductivity | | | | Adhesion to ITO | |
|---|---|---|---|---|---|---|---|
| | patterning | Specific resistivity (Ωcm) | | | | after testing in | Bending |
| | properties | 140° C. | | | 120° C. | high-temperature | resistance |
| | Developable | Curing for | Curing for | Curing for | Curing for | and high-humidity | change |
| | L/S (μm/μm) | 15 minutes | 30 minutes | 60 minutes | 30 minutes | environments | ratio (%) |
| Example 1 | 10/10 | 8.1 × 10⁻⁵ | 7.5 × 10⁻⁵ | 7.1 × 10⁻⁵ | 8.9 × 10⁻⁵ | 100 | 120 |
| Example 2 | 10/10 | 9.1 × 10⁻⁵ | 8.1 × 10⁻⁵ | 7.7 × 10⁻⁵ | 1.1 × 10⁻⁴ | 100 | 120 |
| Example 3 | 10/10 | 8.4 × 10⁻⁵ | 7.2 × 10⁻⁵ | 6.9 × 10⁻⁵ | 9.4 × 10⁻⁵ | 100 | 120 |
| Example 4 | 10/10 | 8.8 × 10⁻⁵ | 7.7 × 10⁻⁵ | 6.6 × 10⁻⁵ | 1.8 × 10⁻⁴ | 100 | 120 |
| Example 5 | 10/10 | 9.4 × 10⁻⁵ | 8.4 × 10⁻⁵ | 7.2 × 10⁻⁵ | 2.1 × 10⁻⁴ | 100 | 120 |
| Example 6 | 10/10 | 9.2 × 10⁻⁵ | 8.5 × 10⁻⁵ | 7.6 × 10⁻⁵ | 2.3 × 10⁻⁴ | 100 | 120 |
| Example 7 | 10/10 | 8.2 × 10⁻⁵ | 7.5 × 10⁻⁵ | 6.4 × 10⁻⁵ | 2.2 × 10⁻⁴ | 100 | 120 |
| Example 8 | 10/10 | 9.2 × 10⁻⁵ | 8.1 × 10⁻⁵ | 7.4 × 10⁻⁵ | 2.4 × 10⁻⁴ | 100 | 120 |
| Example 9 | 10/10 | 9.4 × 10⁻⁵ | 8.3 × 10⁻⁵ | 7.5 × 10⁻⁵ | 2.9 × 10⁻⁴ | 100 | 120 |
| Example 10 | 10/10 | 9.4 × 10⁻⁵ | 8.1 × 10⁻⁵ | 7.2 × 10⁻⁵ | 2.4 × 10⁻⁴ | 100 | 120 |
| Example 11 | 10/10 | 8.4 × 10⁻⁵ | 8.1 × 10⁻⁵ | 6.8 × 10⁻⁵ | 1.9 × 10⁻⁴ | 100 | 120 |
| Example 12 | 10/10 | 9.2 × 10⁻⁵ | 8.3 × 10⁻⁵ | 6.8 × 10⁻⁵ | 2.4 × 10⁻⁴ | 100 | 120 |
| Example 13 | 10/10 | 8.7 × 10⁻⁵ | 7.5 × 10⁻⁵ | 7.5 × 10⁻⁵ | 2.7 × 10⁻⁴ | 100 | 120 |
| Example 14 | 10/10 | 9.5 × 10⁻⁵ | 8.5 × 10⁻⁵ | 8.1 × 10⁻⁵ | 2.9 × 10⁻⁴ | 100 | 120 |
| Example 15 | 10/10 | 9.8 × 10⁻⁵ | 9.1 × 10⁻⁵ | 8.5 × 10⁻⁵ | 2.8 × 10⁻⁴ | 100 | 120 |
| Example 16 | 10/10 | 9.8 × 10⁻⁵ | 9.1 × 10⁻⁵ | 8.4 × 10⁻⁵ | 2.7 × 10⁻³ | 100 | 120 |
| Example 17 | 10/10 | 1.2 × 10⁻⁴ | 9.9 × 10⁻⁵ | 8.9 × 10⁻⁵ | 4.7 × 10⁻³ | 100 | 120 |
| Example 18 | 10/10 | 1.5 × 10⁻⁴ | 1.2 × 10⁻⁴ | 9.1 × 10⁻⁵ | 6.7 × 10⁻³ | 100 | 120 |
| Example 19 | 10/10 | 1.5 × 10⁻⁴ | 1.3 × 10⁻⁴ | 9.7 × 10⁻⁵ | 6.9 × 10⁻³ | 100 | 120 |
| Example 20 | 10/10 | 1.7 × 10⁻⁴ | 1.2 × 10⁻⁴ | 9.3 × 10⁻⁵ | 6.3 × 10⁻³ | 100 | 120 |
| Example 21 | 10/10 | 1.8 × 10⁻⁴ | 1.4 × 10⁻⁴ | 1.0 × 10⁻⁴ | 7.1 × 10⁻³ | 100 | 120 |
| Example 22 | 10/10 | 1.3 × 10⁻⁴ | 9.5 × 10⁻⁵ | 8.8 × 10⁻⁵ | 8.9 × 10⁻² | 100 | 120 |
| Example 23 | 10/10 | 1.4 × 10⁻⁴ | 1.2 × 10⁻⁴ | 9.0 × 10⁻⁵ | 8.9 × 10⁻² | 100 | 120 |
| Example 24 | 10/10 | 1.2 × 10⁻² | 1.0 × 10⁻³ | 9.4 × 10⁻⁴ | 78 | 100 | 120 |
| Example 25 | 10/10 | 1.4 × 10⁻³ | 5.5 × 10⁻⁴ | 1.4 × 10⁻⁴ | 8 | 100 | 120 |
| Example 26 | 10/10 | 8.2 × 10⁻⁵ | 7.7 × 10⁻⁵ | 6.4 × 10⁻⁵ | 8.5 × 10⁻⁵ | 100 | 120 |
| Example 27 | 10/10 | 1.9 × 10⁻⁴ | 1.5 × 10⁻⁴ | 1.1 × 10⁻⁴ | 2.5 × 10⁻⁴ | 100 | 120 |
| Example 28 | 15/15 | 9.1 × 10⁻⁵ | 7.9 × 10⁻⁵ | 7.2 × 10⁻⁵ | 9.5 × 10⁻⁵ | 100 | 120 |
| Example 29 | 10/10 | 8.9 × 10⁻⁵ | 7.2 × 10⁻⁵ | 6.9 × 10⁻⁵ | 1.5 × 10⁻⁴ | 100 | 120 |
| Example 30 | 7/7 | 9.1 × 10⁻⁵ | 7.7 × 10⁻⁵ | 7.2 × 10⁻⁵ | 8.1 × 10⁻⁵ | 100 | 110 |
| Example 31 | 7/7 | 8.9 × 10⁻⁵ | 7.1 × 10⁻⁵ | 6.8 × 10⁻⁵ | 7.3 × 10⁻⁵ | 100 | 100 |
| Example 32 | 7/7 | 2.1 × 10⁻⁴ | 1.8 × 10⁻⁴ | 1.1 × 10⁻⁴ | 1.9 × 10⁻⁴ | 100 | 100 |
| Example 33 | 7/7 | 9.5 × 10⁻⁵ | 8.2 × 10⁻⁵ | 7.4 × 10⁻⁵ | 9.1 × 10⁻⁵ | 100 | 100 |
| Example 34 | 15/15 | 9.5 × 10⁻⁵ | 8.2 × 10⁻⁵ | 7.4 × 10⁻⁵ | 8.4 × 10⁻⁵ | 100 | 120 |
| Example 35 | 15/15 | 8.2 × 10⁻⁵ | 7.2 × 10⁻⁵ | 6.2 × 10⁻⁵ | 8.4 × 10⁻⁵ | 100 | 140 |
| Example 36 | 30/30 | 8.1 × 10⁻⁵ | 7.4 × 10⁻⁵ | 6.4 × 10⁻⁵ | 8.9 × 10⁻⁵ | 100 | 120 |
| Example 37 | 7/7 | 9.4 × 10⁻⁵ | 7.9 × 10⁻⁵ | 6.8 × 10⁻⁵ | 1.7 × 10⁻⁴ | 100 | 100 |
| Example 40 | 15/15 | | 1.2 × 10⁻⁴ | | | | |
| Comparative | 10/10 | Without | Without | Without | Without | 100 | Without |
| Example 1 | | conduction | conduction | conduction | conduction | | conduction |
| Comparative | 10/10 | Without | 1.2 × 10⁻² | 6.9 × 10⁻⁵ | Without | 46 | 180 |
| Example 2 | | conduction | | | conduction | | |
| Comparative | 10/10 | Without | Without | Without | Without | 100 | Without |
| Example 3 | | conduction | conduction | conduction | conduction | | conduction |
| Comparative | 15/15 | | Without | | | | |
| Example 6 | | | conduction | | | | |

TABLE 6

| | Sensing | Environmental | |
|---|---|---|---|
| | properties | burden resistance | Measurement of |
| | (%) | (%) | capacitance |
| Example 38 | 12 | 10 | Good |
| Example 39 | 30 | 25 | Good |
| Comparative | <5 | <5 | Poor |
| Example 4 | | | |
| Comparative | Impossible to | Impossible to | Poor |
| Example 5 | form sensor | form sensor | |

All the photosensitive conductive pastes of Examples 1 to 37 are excellent in fine patterning properties, and it was possible to form a conductive pattern having excellent conductivity, adhesion to ITO after testing in high-temperature and high-humidity environments and bending resistance by short-time curing. Meanwhile, the photosensitive conductive pastes of Comparative Examples 1 to 3 that include no quaternary ammonium salt compound could not simultaneously satisfy conductivity by short-time curing, adhesion to ITO after testing in high-temperature and high-humidity environments, and bending resistance.

### INDUSTRIAL APPLICABILITY

Our photosensitive conductive paste and our film for forming a conductive pattern can be suitably used for the production of peripheral wirings for a touch panel, electrodes for a view area, pressure sensors, conductive patterns on a wiring board and the like.

1-8. (canceled)

9. A photosensitive conductive paste comprising a quaternary ammonium salt compound (A), a carboxyl group-containing resin (B), a photopolymerization initiator (C), a reactive monomer having an unsaturated double bond (D) and conductive particles (E).

10. The photosensitive conductive paste according to claim 9, comprising the quaternary ammonium salt compound (A) in an amount of 0.01 to 5 parts by weight based on 100 parts by weight of the conductive particles (E).

11. The photosensitive conductive paste according to claim 9, wherein a ratio of anions in the quaternary ammonium salt compound (A) is 10.0% by weight or more.

12. The photosensitive conductive paste according to claim 9, wherein the quaternary ammonium salt compound (A) has a molecular weight of 350 or less.

13. The photosensitive conductive paste according to claim 9, wherein at least three of groups bonded to nitrogen atoms of the quaternary ammonium salt compound (A) are CₓH₂ₓ₋₁ (x=1 to 4).

14. A film for forming a conductive pattern, comprising a releasable film and a dried film of the photosensitive conductive paste according to claim 9, wherein the dried film is laminated on the releasable film.

15. A pressure sensor comprising a cured product of the photosensitive conductive paste according to claim 9 formed on at least one surface of an elastic body having a melting point of 140° C. or higher.

16. A method of producing a substrate with wiring, comprising:
subjecting the dried film in the film for forming a conductive pattern according to claim 14 to exposure and development to form a pattern on the releasable film;
laminating the film for forming a conductive pattern on a substrate so that the pattern is brought into contact with the substrate;
heating and pressing the laminate, thereby transferring the pattern to both sides and the end face of the substrate; and
curing the pattern by heating to obtain a substrate with double-sided wiring in which wiring is formed on both sides of the substrate via the end face of the substrate.
